(19) United States
(12) Patent Application Publication
(10) Pub. No.: US 2024/0160808 A1
(43) Pub. Date: May 16, 2024

(54) METHOD AND SYSTEM FOR SIMULATING SOUND OF VEHICLE GEAR-SHIFTING

(71) Applicant: Harman Becker Automotive Systems GmbH, Karlsbad-Ittersbach (DE)

(72) Inventors: Xiaoke Pang, Suzhou, Jiangsu (CN); Jianbo Lu, Suzhou, Jiangsu (CN); Gengen Su, Suzhou, Jiangsu (CN)

(21) Appl. No.: 18/550,283

(22) PCT Filed: Apr. 12, 2021
(86) PCT No.: PCT/CN2021/086630

§ 371 Date: Sep. 12, 2023

(51) Int. Cl. G06F 30/20; B60Q 9/00

(52) U.S. Cl. CPC G06F 30/20; B60Q 9/00

(57) ABSTRACT

The disclosure provides a method and a system for generating simulated engine sounds for simulated gear-shifting of a vehicle. The method may comprise mapping a plurality of operating conditions of the vehicle to a plurality of respective simulated gears, wherein each of the operating conditions is associated with a throttle position and a vehicle speed. The method may further comprise configuring a plurality of simulated gear-shifting conditions based on threshold throttle positions and threshold vehicle speeds for simulated gear-shifting among respective simulated gears, wherein for each gear-shifting condition, at least some of the threshold vehicle speeds vary dependent of the throttle positions. The method may further comprise receiving conditions of the vehicle, and selecting a simulated gear in response to the operating conditions.

### TECHNICAL FIELD

The present disclosure relates generally to generating simulated vehicle sounds and, more particularly to, method and system for generating simulated sounds associated with operation of a multi-gear vehicle.

### BACKGROUND

In recent years, electric and hybrid vehicles are becoming increasingly popular. However, electric vehicles typically may not have desired characteristics found in combustion-engine vehicles. Among those characteristics are the sounds associated with an engine accelerating and shifting gears, either automatically or through manual control. Therefore, a need exists to provide simulated vehicle sound generation to provide a simulated audio experience of combustion-engine vehicles for the driver.

The current simulation sound approach usually considers only fixed threshold vehicle speed for each gear of the gearbox of the vehicle as a condition for shifting, and outputs the sound of the corresponding gear when the fixed threshold vehicle speed is reached. However, this method causes the generated simulated sound to be very unnatural, because the various situations of the actual operation of the vehicle are not considered, and therefore, a good driving experience cannot be brought to the user.

Therefore, it is necessary to provide an improved technology to output a more realistic simulated engine sound of gear-shifting of gearbox, so as to bring a better driving experience to the drivers.

### SUMMARY

According to one or more embodiments of the disclosure, a method for generating simulated engine sounds for simulated gear-shifting of a vehicle is provided. The method may comprise mapping a plurality of operating conditions of the vehicle to a plurality of respective simulated gears, wherein each of the operating conditions is associated with a throttle position and a vehicle speed. The method may further comprise configuring a plurality of simulated gear-shifting conditions based on threshold throttle positions and threshold vehicle speeds for simulated gear-shifting among respective simulated gears, wherein for each gear-shifting condition, at least some of the threshold vehicle speeds vary dependent of the throttle positions. The method may further comprise receiving a first operating condition of the vehicle, and selecting a first simulated gear from a plurality of respective simulated gears in response to the received first operating condition of the vehicle; generating a first engine sound signal corresponding to the first simulated gear; receiving a second operating condition of the vehicle; determining a gear-shifting from the first simulated gear to a second simulated gear if the second operation condition reaches one of the plurality of simulated gear-shifting conditions; and generating a second engine sound signal corresponding to the second simulated gear.

According to one or more embodiments of the disclosure, a system generating simulated engine sounds for simulated gear-shifting of a vehicle is provided. The system may comprise a storage device and a processor. The storage device may be configured to store a mapping of a plurality of operating conditions of the vehicle to a plurality of respective simulated gears, wherein each of the operating conditions is associated with a throttle position and a vehicle speed; and store a plurality of simulated gear-shifting conditions configured based on threshold throttle positions and threshold vehicle speeds for simulated gear-shifting among respective simulated gears, wherein for each gear-shifting condition, at least some of the threshold vehicle speeds vary dependent of the throttle positions. The processor may be configured to receive a first operating condition of the vehicle, and select a first simulated gear from a plurality of respective simulated gears in response to the received first operating condition of the vehicle; generate a first engine sound signal corresponding to the first simulated gear; receive a second operating condition of the vehicle; determine a gear-shifting from the first simulated gear to a second simulated gear if the second operation condition reaches one of the plurality of simulated gear-shifting conditions; and generate a second engine sound signal corresponding to the second simulated gear.

### BRIEF DESCRIPTION OF THE DRAWINGS

FIG. 1 illustrates a schematic diagram of the system of generating simulated vehicle sounds in accordance with one or more embodiments of the present disclosure;

FIG. 2 illustrates an example plot of vehicle speed versus throttle position for upshifting of the gearbox of the vehicle in accordance with one or more embodiments of the present disclosure;

FIG. 3 illustrates an example plot of vehicle speed versus throttle position for downshifting of the gearbox of the vehicle in accordance with one or more embodiments of the present disclosure;

FIG. 4A-FIG. 4C illustrate example upshifting situations based on the plots of vehicle speed versus throttle position for upshifting in accordance with one or more embodiments of the present disclosure;

FIG. 5A-FIG. 5B illustrates example downshifting situations based on the plots of vehicle speed versus throttle position for downshifting in accordance with one or more embodiments of the present disclosure;

FIG. 6 illustrates another example plot of vehicle speed versus throttle position for downshifting of the gearbox of the vehicle in accordance with one or more embodiments of the present disclosure;

FIG. 7 illustrates another example plot of vehicle speed versus throttle position for downshifting of the gearbox of the vehicle in accordance with one or more embodiments of the present disclosure;

FIG. 8 illustrates an example plot of vehicle speed versus engine RPM (Rotation Per Minute) for multiple gears of the gearbox of the vehicle in accordance with one or more embodiments of the present disclosure;

FIG. 9 illustrates a method flowchart of generating simulated vehicle sounds in accordance with one or more embodiments of the present disclosure.

To facilitate understanding, identical reference numerals have been used, where possible, to designate identical elements that are common to the figures. It is contemplated that elements disclosed in one embodiment may be beneficially utilized on other embodiments without specific recitation. The drawings referred to here should not be understood as being drawn to scale unless specifically noted. Also, the drawings are often simplified and details or components omitted for clarity of presentation and explanation. The drawings and discussion serve to explain principles discussed below, where like designations denote like elements.

### DETAILED DESCRIPTION OF THE PREFERRED EMBODIMENTS

Examples will be provided below for illustration. The descriptions of the various examples will be presented for purposes of illustration, but are not intended to be exhaustive or limited to the embodiments disclosed. Many modifications and variations will be apparent to those of ordinary skill in the art without departing from the scope and spirit of the described embodiments.

In general, the present disclosure provides a system and a method for generating simulated engine sounds for simulated gear-shifting of a vehicle. In some embodiments, the method may map a plurality of operating conditions of the vehicle to a plurality of respective simulated gears, each of the operating conditions is associated with a throttle position and a vehicle speed. The method may further design simulated gear-shifting conditions based on threshold throttle positions and threshold vehicle speeds for simulated gear-shifting among the simulated gears. At least some of the threshold vehicle speeds for simulated gear-shifting may vary as the throttle positions. The method may determine if a simulated gear-shifting will be triggered in response to the received operating condition of the vehicle, and generate engine sound single to drive at least one sound generation device of the vehicle to produce the corresponding sound to simulate the operation at the shifted simulated gear. The method and system of the present disclosure designs/configures/plots simulated gear-shifting conditions with the threshold vehicle speeds for simulated gear-shifting varying as the throttle positions, which simulates the realistic situations during the driving. Compared with the existing approach, the method and system described in the present disclosure can output more realistic sound to make the user have better driving experience.

The vehicle described herein may be a fully or partially-electric vehicle. The vehicle may be driven by an electric motor. In other examples, the vehicle may be driven by a combination of an electric motor and an internal combustion engine (hybrid electric vehicle). The motor of the vehicle may generate sounds different than those that may be heard by vehicle occupants in other vehicles types, such as a vehicle having an internal combustion engine. Occupants of an electric vehicle may desire to experience sounds associated with an internal combustion engine or other sound effect.

In some embodiments, the vehicle may include an audio system which may be located in a dashboard of the vehicle. The audio system may include various components, such as AM/FM radio, CD player, cassette deck, personal music player input connector, equalizer, amplifier, cellular telephone interface, navigation system, and any other components suitable for a vehicle audio system. The audio system may be two channel stereo or multi-channel, such as a five, six, or seven channel surround system. The audio system may include software modules, hardware modules, or a combination thereof used to process audio signals provided to a plurality of speakers throughout the vehicle.

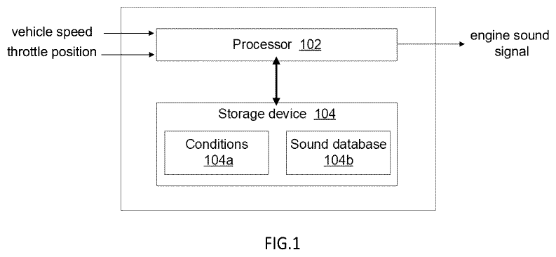

FIG. 1 illustrates a schematic diagram of a system of generating simulated vehicle sounds within the vehicle in accordance with one or more embodiments of the present disclosure. The system may be a separated system from the audio system of the vehicle, or may be combined or integrated in the audio system of the vehicle. For example, the system may produce audible sound through one more of the loud speakers in the vehicle.

As shown in FIG. 1, the system may comprise a processor 102 and a storage device 104. The processor 102 may be any technically feasible hardware unit configured to process data and execute software applications, including without limitation, a central processing unit (CPU), a microcontroller unit (MCU), an application specific integrated circuit (ASIC), a digital signal processor (DSP) chip and so forth. Various processing techniques may be implemented by the processor 102 such as multiprocessing, multitasking, parallel processing and the like, for example. The processor 102 may include one or more processors.

The storage device 104 may include one or more memories and may be computer-readable storage media or memories, such as a cache, buffer, removable media, hard drive or other computer readable storage media. The storage device 104 may include, without limitation, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing.

In some embodiments, the storage device 104 may include conditions storage unit 104a for storing, for example, the mapping of the operating conditions of the vehicle and the respective simulated gears of the gearbox, and simulated gear-shifting conditions for gearbox. In some embodiments, each of the operating conditions may be associated with a throttle position and a vehicle speed of the vehicle. In some embodiments, the gear-shifting conditions may be designed/configured/predetermined based on threshold throttle positions and threshold vehicle speeds for simulated gear-shifting among respective simulated gears, wherein for each gear-shifting condition, at least some of the threshold vehicle speeds for simulated gear-shifting may vary dependent of the throttle positions. In some embodiments, the storage device 104 may further comprise simulated sound database 104b which may comprises sound data representing various sounds respectively corresponding to the respective operations at respective simulated gears.

The processor 102 may receive the current operation condition associated with the current vehicle speed and the current throttle position. For example, the vehicle speed and the throttle position may be detected by sensors positioned in/on the vehicle. The processor may determine the current simulated gear based on the current vehicle speed and the current throttle position according to the mapping of the operation condition and the corresponding simulated gear stored in the storage device 104. Upon the operation condition of the vehicle changes, the processor may determine if the new operation condition reaches one of the gear-shifting conditions. If the new operation condition reaches one gear-shifting condition, the processor may generate a simulated engine sound signal corresponding to the operation indicated by the gear-shifting condition. Then, the simulated engine sound signal may be used to drive the at least one the loudspeakers to output the respective sound to simulate the operation at the new gear.

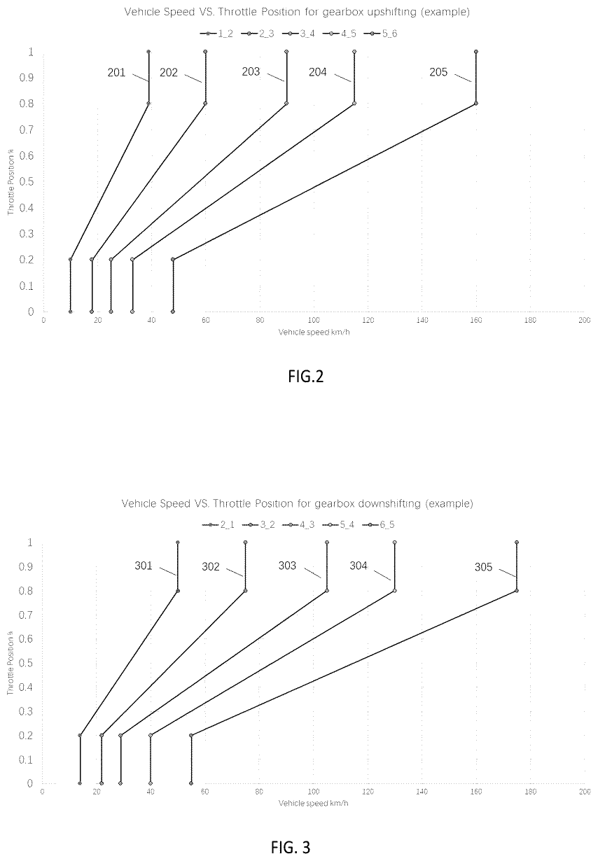

In some embodiments, gear-shifting lines may be designed/configured/plotted to simulate the gear-shifting of the gearbox in the real driving according to different type of vehicle or different requirements from the driving experience. FIG. 2 and FIG. 3 respectively show two different plots in different gearbox shifting modes, each plot may comprises a plurality of gear-shifting lines respectively represent different simulated gear-shifting conditions. FIG. 2 illustrates an example plot of vehicle speed versus throttle position for gear-shifting in gearbox upshifting mode in accordance with one or more embodiments of the present disclosure. FIG. 3 illustrates an example plot of vehicle speed versus throttle position for gear-shifting in gearbox downshifting mode in accordance with one or more embodiments of the present disclosure. Those skilled in the art will understand that all these lines in FIG. 2 and FIG. 3 may be plotted in one plot.

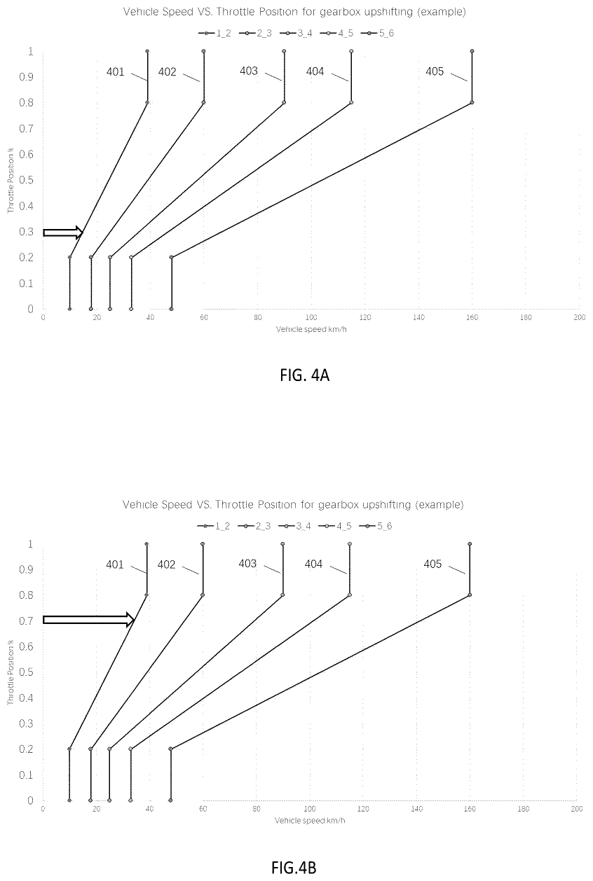

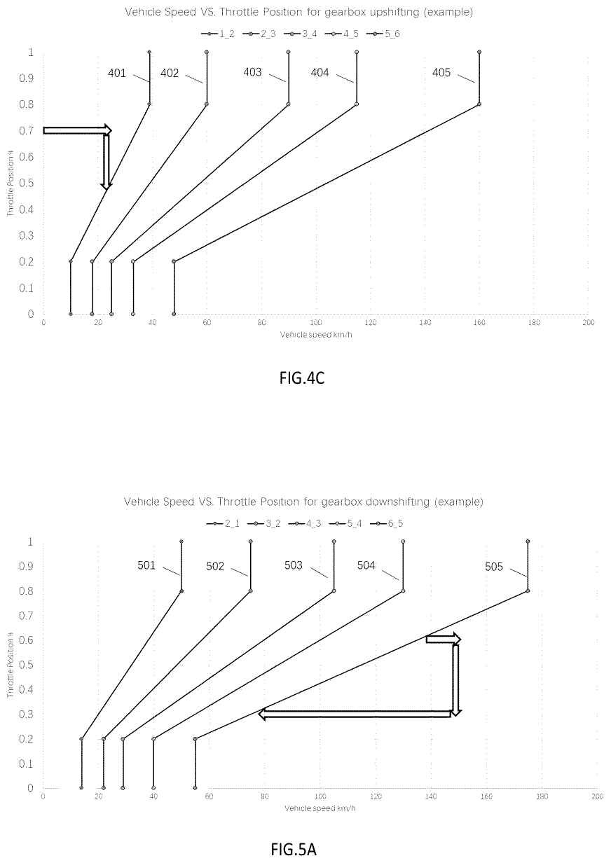

Referring to FIG. 2, the plot of FIG. 2 shows five gear-shifting lines of the gearbox of vehicle, as an example. Each of the gear-shifting lines represents a simulated gear-shifting condition for each simulated gear-shifting among the plurality of respective simulated gears. For example, line 201 represents the gear-shifting condition for the simulated shifting of the gearbox from gear 1 to gear 2, line 202 represents the gear-shifting condition for the simulated shifting of the gearbox from gear 2 to gear 3, line 203 represents the gear-shifting condition for the simulated shifting of the gearbox from gear 3 to gear 4, line 204 represents the gear-shifting condition for the simulated shifting of the gearbox from gear 4 to gear 5, and line 205 represents the gear-shifting condition for the simulated shifting of the gearbox from gear 5 to gear 6. In some embodiments, each of the lines 201-205 may be designed/configured/plotted based on threshold throttle positions and threshold vehicle speeds for the simulated upshifting of the gearbox. In some embodiments, each of the gear-shifting lines 201-205 is configured so that at least some of threshold vehicle speeds increases with the threshold throttle positions increase. In some embodiments, the gear-shifting lines 201-205 are configured so that, for the same the threshold throttle position, the current gear is higher, the threshold vehicle speeds for gear-shifting is higher. In some embodiments, these threshold throttle positions and threshold vehicle speeds may be determined according to the gear-shifting logics. The logics may include the simulated upshift and downshift of various operation conditions while driving, which will be later described in details in reference to FIGS. 4A-4C.

Referring to FIG. 3, the plot of FIG. 3 shows five gear-shifting lines of the gearbox of vehicle, as an example. Each of the gear-shifting lines represents a simulated gear-shifting condition for each simulated gear-shifting among the plurality of respective simulated gears. For example, line 301 represents the gear-shifting condition for the simulated shifting of the gearbox from gear 2 to gear 1, line 302 represents the gear-shifting condition for the simulated shifting of the gearbox from gear 3 to gear 2, line 303 represents the gear-shifting condition for the simulated shifting of the gearbox from gear 4 to gear 3, line 304 represents the gear-shifting condition for the simulated shifting of the gearbox from gear 5 to gear 4, and line 305 represents the gear-shifting condition for the simulated shifting of the gearbox from gear 6 to gear 5. In some embodiments, each of the lines 301-305 may be designed/configured/plotted based on threshold throttle positions and threshold vehicle speeds for the simulated downshifting of the gearbox. In some embodiments, each of the gear-shifting lines 301-305 is configured so that at least some of threshold vehicle speeds increases with the threshold throttle positions increase. In some embodiments, the gear-shifting lines 301-305 are configured so that, for the same the threshold throttle position, the current gear is higher, the threshold vehicle speeds for gear-shifting is higher. In some embodiments, these threshold throttle positions and threshold vehicle speeds may be determined according to the gear-shifting logics. The logics may include the simulated upshift and downshift of various operation conditions while driving, which will be later described in details in reference to FIGS. 5A-5B.

FIG. 4A shows an example for illustrating the simulated gear-shifting operation according to the designed gear-shifting lines. Referring to FIG. 4A, lines 401-405 are the configured upshifting condition lines which represent respectively different simulated gear-shifting conditions similar as that of FIG. 2. For example, if the vehicle starts with a constant lower throttle position (e.g. 30% throttle), as shown by the arrow in FIG. 4A, the vehicle speed rises from 0, and the throttle position remains 30%. When the arrow reaches the line 401 (e.g., the vehicle speed is about 16 km/h), it means the current operation condition of the vehicle meets the simulated gear-shifting condition, such as upshifting from gear 1 to gear 2. Thus, upon reaching the line 401, the corresponding simulated sound may be generated to simulate the upshift operation of the gearbox from gear 1 to gear 2. Next, the further simulated sound may be generated to simulate the operation in gear 2. For example, the simulated sound for the engine may vary as the vehicle speed increases, to simulate the accelerating operation in gear 2. It can be further seen, for example, if keeping the throttle position constant, as the vehicle speed gradually rises, the arrow may cross the lines such as line 402, 403, 404 and 405 until reaching a certain speed and gear, in which the resistance and power may reach a balance. At this time, the vehicle may drive at this speed at a constant speed.

FIG. 4B shows another example for illustrating the simulated gear-shifting operation according to the designed gear-shifting lines. Referring to FIG. 4B, lines 401-405 are the upshifting condition lines which respectively represent different simulated gear-shifting conditions as described in reference to FIG. 2. For example, if the vehicle stars with a constant higher throttle position (e.g. 70% throttle), as shown by the arrow in FIG. 4B, the vehicle speed rises from 0, and the throttle position remains 70%. When the arrow reaches the line 401, it means the current operation condition of the vehicle meets the simulated gear-shifting condition, such as upshifting from gear 1 to gear 2. Upon reaching the line 401 (e.g., the vehicle speed is about 33 km/h), the simulated sound may be generated to simulate the upshift operation of the gearbox from gear 1 to gear 2. Next, the further simulated sound may be generated to simulate the operation in gear 2. For example, the simulated sound for the engine may vary as the vehicle speed increases, to simulate the accelerating operation in gear 2. It can be seen, for example, if keeping the throttle position constant, as the vehicle speed gradually rises, the arrow may cross the lines such as line 402, 403, 404 and 405 until reaching a certain speed and gear, in which the resistance and power may reach a balance.

Compared with the case of starting from the 30% throttle position shown in FIG. 4A, in the case of FIG. 4B with starting from the 70% throttle position, the threshold vehicle speed for upshifting is significantly increased, and thus the simulated engine speed is also higher (which will be referred to and described later in reference to FIG. 8). That means, the gear-shifting lines representing simulated gear-shifting conditions are designed/configured/simulated based on threshold throttle positions and threshold vehicle speeds for simulated gear-shifting among the different gears of the gearbox, wherein at least some of the threshold vehicle speeds for simulated gear-shifting may vary depending on the throttle positions. For example, FIG. 4A shows the gear-shifting condition for upshifting from gear 1 to gear 2 is met when the operation condition of the vehicle changes and reaches the gear-shifting line (threshold gear-shifting conditions, e.g., the threshold vehicle speed 16 km/h at 30% throttle position). FIG. 4B shows the gear-shifting condition for upshifting from gear 1 to gear 2 is met when the operation condition of the vehicle changes and reaches the gear-shifting line (threshold gear-shifting conditions, e.g., the threshold vehicle speed 33 km/h at 70% throttle position). That is, the threshold vehicle speed for gear-shifting varies dependent of the threshold throttle position. This simulation may corresponding to the operation of the gearbox with some type of vehicle. Such a simulation design is closer to the actual driving situation of the vehicle.

FIG. 4C shows another example for illustrating the simulated gear-shifting operation according to the designed gear-shifting lines. Referring to FIG. 4C, lines 401-405 are the upshifting condition lines which respectively represent different simulated gear-shifting conditions as described in reference to FIG. 2. For example, if the vehicle stars with a constant higher throttle position (e.g. 70% throttle), as shown by the arrow in FIG. 4C, the vehicle speed rises from 0, and the throttle position remains 70%. The vehicle speed reaches about 22 km/h and has not reached the gear-shifting line, but if the driver decreases the throttle position at this time (see the down arrow), it can be seen that when the throttle position is about 47%, the arrow reaches the line 401, which means the operation condition of the vehicle meets the simulated gear-shifting condition, such as upshifting from gear 1 to gear 2. Upon reaching the line 401, the simulated sound may be generated to simulate the upshift operation of the gearbox from gear 1 to gear 2. Next, the further simulated sound may be generated to simulate the operation in gear 2. For example, the simulated sound for the engine may vary as the vehicle speed increases, to simulate the accelerating operation in gear 2. FIG. 4C simulates the cases of changing the throttle position from higher to lower to achieve the purpose, such as fast upshifting and obtain better dynamics.

FIGS. 4A-4C only illustrate that the simulated upshift lines designed according to one or more embodiments of the present disclosure is more flexible and realistically reflects the upshift situation in the real driving, but not intended to exhaust or limit the upshift occurring during the driving.

FIGS. 5A-5B illustrates examples of the simulated downshifting lines of the gearbox designed according to one or more embodiment of the present disclosure. For the purpose of explanation, FIG. 5A shows a case, wherein the vehicle is traveling at about 60% throttle position and about vehicle speed 150 km/h. when the driver wants to lower the speed, he/she may raise the accelerator pedal and thus reduce the throttle position for example from 60% to 30%, and the speed will decrease accordingly. When the vehicle speed drops to about 75 km/h, the downshift condition is triggered, such as from the sixth gear to the fifth gear. Then, if the throttle position remains, it can be seen that the gearbox may be gradually down to the forth, third, second, and the first gear until the vehicle stops.

FIG. 5B illustrates another example case for simulated gear-shifting. As the arrow shown in FIG. 5B, when the car is driving at 20% throttle position and 80 km/h, suddenly depressing the accelerator pedal increases the throttle position to 70%. It can be seen from FIG. 5B that when the throttle position is about 33%, the downshift condition, such as downshifting from the sixth gear to the fifth gear, is triggered. When the throttle position is about 47%, the downshift condition, such as downshifting from the fifth gear to the fourth gear, is triggered. When the throttle position is about 60%, the downshift condition, such as downshifting from the fourth gear to the third gear, is triggered. It can be understood that if such a throttle position is maintained, then as the vehicle speed increases, the gearbox will continue to increase to the fourth and fifth gears.

FIGS. 5A-5B only illustrate that the simulated downshift lines designed according to one or more embodiments of the present disclosure is more flexible and realistically reflects the downshift situation in the real driving, but not intended to exhaust or limit the downshift occurring during the driving.

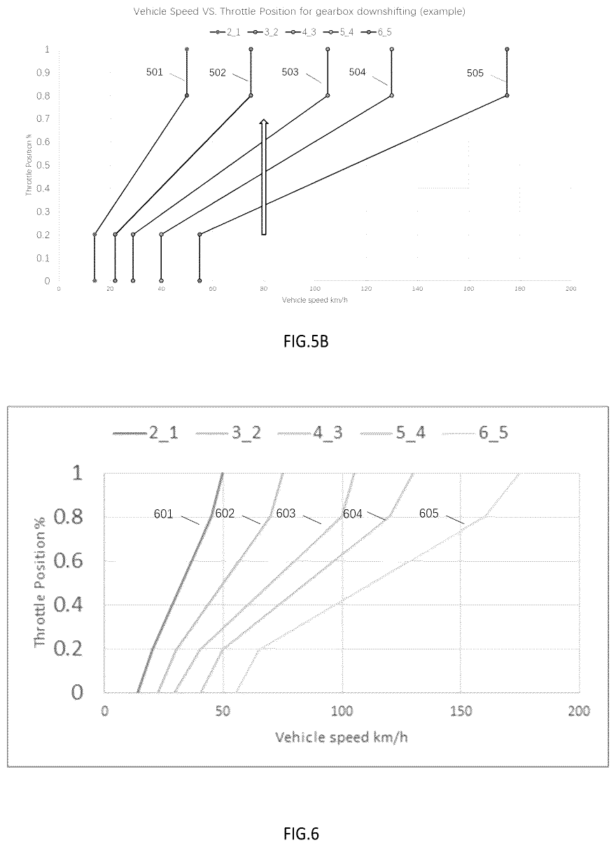

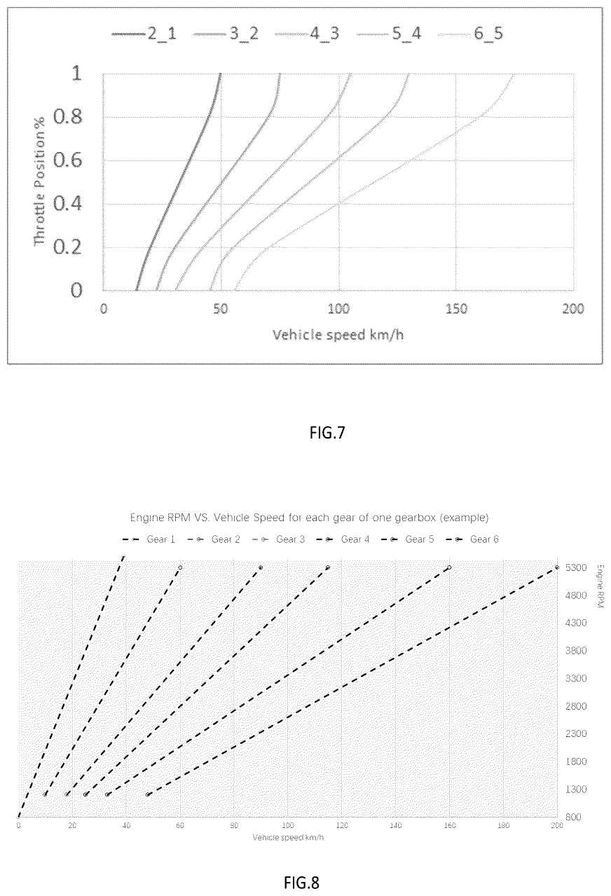

It will be understood that FIGS. 2-5B are only to illustrate that the simulation performed by the method and system of the present disclosure can be closer to the real driving situation. This is because the design of the shift conditions of the present disclosure adopts both the vehicle speed and the throttle position, and the shift threshold vehicle speed changes with the change of the threshold throttle position. This kind of simulation is closer to the shifting situation in real driving. The lines in FIGS. 2-5B are only exemplary and are not intended to limitation. According to the requirements of customers and the market, different simulated gear-shifting conditions can be designed for different models of vehicles, that is, different simulated gear-shifting lines can be generated. FIGS. 6-7 respectively show the gear-shifting condition curves that can be adjusted according to different requirements. The curves in FIGS. 6-7 are only exemplary and are not intended to limitation.

FIG. 8 illustrates an example plot of simulated engine RPM verse vehicle speed for each gear of the gearbox in accordance with one or more embodiments of the present disclosure. FIG. 8 shows an example mapping of the vehicle speed to an engine RPM for each gear of the gearbox. The lines shown in FIG. 8, from left to right, respectively correspond to the mapping in gear 1, gear 2, gear 3, gear 4, gear 5 and gear 6. The mapping may be pre-stored in the storage device, such as the storage device 104. For example, the processor may determine the current simulated gear based on the operation condition of the vehicle, and then the processor may retrieve the mapping from the storage device and determine the corresponding engine RPM based on the current vehicle speed. In the current gear, the processor may generate an engine sound signal to drive at least one sound generation device of the vehicle (for example, at least one loudspeakers mounted in/on the vehicle) to produce the sound to simulate the operation in the current simulated gear. In some embodiments, sounds for the current gear may vary as the engine RPM or the vehicle speed varies, for example based on the sounds stored in the sound database 104b. The sound database 104b may store various sound for different simulated gears and store the mapping of the sound to the engine RPM or the vehicle speed for each gear.

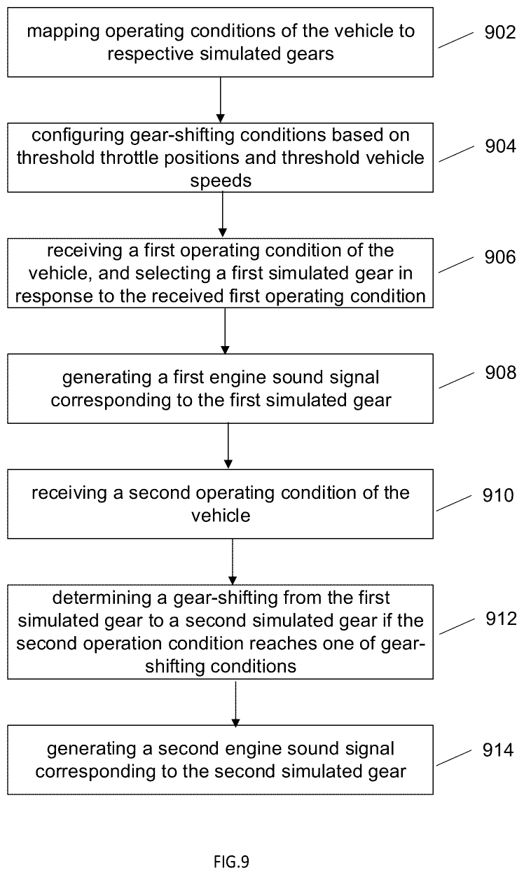

FIG. 9 illustrates a method flowchart of generating simulated engine sounds in accordance with one or more embodiments of the present disclosure. At 5902, a plurality of operating conditions of the vehicle may be mapped to a plurality of respective simulated gears. Each of the operating conditions is associated with a throttle position and a vehicle speed. Taking FIG. 2 as an example, the operation conditions falling within the left side area of line 201 may correspond to gear 1, the operation conditions falling within the area between line 201 and line 202 may correspond to gear 2, the operation conditions falling within the area between line 202 and line 203 may correspond to gear 3, the operation conditions falling within the area between line 203 and line 204 may correspond to gear 4, the operation conditions falling within the area between line 204 and line 205 may correspond to gear 5, and the operation conditions falling within the right area of line 205 may correspond to gear 6.

At 5904, the simulated gear-shifting conditions may be designed/configured/predetermined/plotted based on threshold throttle positions and threshold vehicle speeds for simulated gear-shifting of the gearbox. Taking FIG. 2 and FIG. 3 as examples, lines 201-205 and lines 301-305 as the simulated gear-shifting conditions are designed based on the threshold throttle positions and threshold vehicle speeds for simulated gear-shifting of the gearbox. For each gear-shifting condition, at least some of the threshold vehicle speeds for simulated gear-shifting vary dependent on the throttle positions. In some embodiments, the simulated gear-shifting conditions may be classified into an upshifting condition set including upshifting conditions and a downshifting condition set including downshifting conditions. In some embodiments, upon receiving the current operation condition associated with the current vehicle speed and the current throttle position, the processor may first determines whether a current throttle position is greater than a predetermined throttle threshold. For example, if the current throttle position is greater than the predetermined throttle threshold, then the processor may determine the gearbox shifting mode as an upshifting mode and the simulated gear-shifting conditions from the upshifting condition set will be used and selected. For example, if the current throttle position is less than or equal to the predetermined throttle threshold, then the processor may determine the gearbox shifting mode as a downshifting mode and the simulated gear-shifting conditions from the downshifting condition set will be used and selected. This classification may reduce the amount of calculation of the hardware processor, thereby reducing the calculation time and increasing the processing speed.

At 5906, for example, a first operating condition of the vehicle may be received. The processor may determine and select, for example a first simulated gear from a plurality of respective simulated gears in response to the received first operating condition of the vehicle. Then, at 5908, a first engine sound signal corresponding to the first simulated gear may be generated, as the foresaid description in reference to FIG. 2-FIG. 5B. In some embodiments, for example, based on the first engine sound signal, at least one sound generation device of the vehicle may be driven to produce the first sound to simulate the operation in the first simulated gear. In some embodiments, sounds may be varied in the first gear as the engine RPM or the vehicle speed varies, for example based on the sounds stored in the sound database.

At 5910, for example, a second operating condition of the vehicle may be received. At 5912, the processor determines whether the second operation condition reaches one of the plurality of simulated gear-shifting conditions. For example, if the second operation condition reaches the second gear-shifting condition that is different from the first gear-shifting condition, the processor may determines a simulated gear shift is needed, such as from the first simulated gear to a second simulated gear. In an upshifting mode, the second simulated gear may be higher than the first simulated gear. In a downshifting mode, the second simulated gear may be lower than the first simulated gear. The first and second simulated gear are described only for the purpose of illustration, instead of limitation.

At 5914, a second engine sound signal corresponding to the second simulated gear may be generated, as the foresaid description in reference to FIG. 2-FIG. 5B. In some embodiments, for example, based on the second engine sound signal, at least one sound generation device of the vehicle may be driven to produce the second sound to simulate the operation in the second simulated gear. In some embodiments, sounds may be varied in the second gear as the engine RPM or the vehicle speed varies, for example based on the sounds stored in the sound database.

1. In some embodiments, a method for generating simulated engine sounds for simulated gear-shifting of a vehicle, the method comprising: mapping a plurality of operating conditions of the vehicle to a plurality of respective simulated gears, wherein each of the operating conditions is associated with a throttle position and a vehicle speed; configuring a plurality of simulated gear-shifting conditions based on threshold throttle positions and threshold vehicle speeds for simulated gear-shifting among respective simulated gears, wherein for each gear-shifting condition, at least some of the threshold vehicle speeds vary dependent of the throttle positions; receiving a first operating condition of the vehicle, and selecting a first simulated gear from a plurality of respective simulated gears in response to the received first operating condition of the vehicle; generating a first engine sound signal corresponding to the first simulated gear; receiving a second operating condition of the vehicle; determining a gear-shifting from the first simulated gear to a second simulated gear if the second operation condition reaches one of the plurality of simulated gear-shifting conditions; and generating a second engine sound signal corresponding to the second simulated gear.

2. The method according to clause 1, further comprising: classifying the simulated gear-shifting conditions into an upshifting condition set of simulated gear-shifting conditions and a downshifting condition set of simulated gear-shifting conditions; determining whether a current throttle position is greater than a predetermined throttle threshold; selecting the simulated gear-shifting conditions from the upshifting condition set of simulated gear-shifting conditions, if the current throttle position is greater than a predetermined throttle threshold; and selecting the simulated gear-shifting conditions from the downshifting condition set of simulated gear-shifting conditions, if the current throttle position is less than or equal to the predetermined throttle threshold.

3. The method according to any one of clauses 1-2, wherein configuring gear-shifting lines based on threshold throttle positions and threshold vehicle speeds for simulated gear-shifting as the simulated gear-shifting conditions, wherein each of the gear-shifting lines represents a gear-shifting condition for a simulated gear-shifting among the plurality of respective simulated gears.

4. The method according to any one of clauses 1-3, wherein each of the gear-shifting lines is configured so that at least some of threshold vehicle speeds increases with the threshold throttle positions increase.

5. The method according to any one of clauses 1-4, wherein the gear-shifting lines are configured so that, for the same the threshold throttle position, the current gear is higher, the threshold vehicle speeds for gear-shifting is higher.

6. The method according to any one of clauses 1-5, wherein the method further comprising: mapping the vehicle speed to an engine RPM for each gear of the gearbox.

7. The method according to any one of clauses 1-6, further comprising: based on the first engine sound signal, driving at least one sound generation device of the vehicle to produce the first sound to simulate the operation in the first simulated gear; and based on the second engine sound signal, driving at least one sound generation device of the vehicle to produce the second sound to simulate the operation in the second simulated gear.

8. The method according to any one of clauses 1-7, wherein driving at least one sound generation device of the vehicle to produce the first sound to simulate the operation in the first simulated gear further comprising: generating varied sounds for the first gear as the engine RPM or the vehicle speed varies; and wherein driving at least one sound generation device of the vehicle to produce the second sound to simulate the operation in the second simulated gear further comprising: generating varied sounds for the second gear as the engine RPM or the vehicle speed varies.

9. In some embodiments, a system for generating simulated engine sounds for simulated gear-shifting of a vehicle comprising: a storage device configured to: store a mapping of a plurality of operating conditions of the vehicle to a plurality of respective simulated gears, wherein each of the operating conditions is associated with a throttle position and a vehicle speed; and store a plurality of simulated gear-shifting conditions configured based on threshold throttle positions and threshold vehicle speeds for simulated gear-shifting among respective simulated gears, wherein for each gear-shifting condition, at least some of the threshold vehicle speeds vary dependent of the throttle positions; and a processor configured to: receive a first operating condition of the vehicle, and select a first simulated gear from a plurality of respective simulated gears in response to the received first operating condition of the vehicle; generate a first engine sound signal corresponding to the first simulated gear; receive a second operating condition of the vehicle; determine a gear-shifting from the first simulated gear to a second simulated gear if the second operation condition reaches one of the plurality of simulated gear-shifting conditions; and generate a second engine sound signal corresponding to the second simulated gear.

10. The system according to clause 9, wherein the simulated gear-shifting conditions are classified into an upshifting condition set of simulated gear-shifting conditions and a downshifting condition set of simulated gear-shifting conditions; and the processor is further configured to: determine whether a current throttle position is greater than a predetermined throttle threshold; select the simulated gear-shifting conditions from the upshifting condition set of simulated gear-shifting conditions, if the current throttle position is greater than a predetermined throttle threshold; and select the simulated gear-shifting conditions from the downshifting condition set of simulated gear-shifting conditions, if the current throttle position is less than or equal to the predetermined throttle threshold.

11. The system according to any one of clauses 9-10, wherein the plurality of simulated gear-shifting conditions further comprising gear-shifting lines configured based on threshold throttle positions and threshold vehicle speeds for simulated gear-shifting as the simulated gear-shifting conditions, wherein each of the gear-shifting lines represents a gear-shifting condition for a simulated gear-shifting among the plurality of respective simulated gears.

12. The system according to any one of clauses 9-11, wherein each of the gear-shifting lines is configured so that at least some of threshold vehicle speeds increases with the threshold throttle positions increase.

13. The system according to any one of clauses 9-12, wherein the gear-shifting lines are configured so that, for the same the threshold throttle position, the current gear is higher, the threshold vehicle speeds for gear-shifting is higher.

14. The system according to any one of clauses 9-13, wherein the storage device is further configured to store the mapping of the vehicle speed to an engine RPM for each gear of the gearbox.

15. The system according to any one of clauses 9-14, wherein the processor is further configured to: drive at least one sound generation device of the vehicle to produce the first sound to simulate the operation in the first simulated gear, based on the first engine sound signal; and drive at least one sound generation device of the vehicle to produce the second sound to simulate the operation in the second simulated gear, based on the second engine sound signal.

16. The system according to any one of clauses 9-15, wherein the processor is further configured to: drive at least one sound generation device of the vehicle to generate varied sounds for the first gear as the engine RPM or the vehicle speed varies; and drive at least one sound generation device of the vehicle to generate varied sounds for the second gear as the engine RPM or the vehicle speed varies.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

In the preceding, reference sign is made to embodiments presented in this disclosure. However, the scope of the present disclosure is not limited to specific described embodiments. Instead, any combination of the preceding features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the preceding aspects, features, embodiments and advantages are merely illustrative and are not considered elements or limitations of the appended claims except where explicitly recited in a claim(s).

Aspects of the present disclosure may take the form of an entirely hardware embodiment, an entirely software embodiment (including firmware, resident software, micro-code, etc.) or an embodiment combining software and hardware aspects that may all generally be referred to herein as a “circuit,” “module” or “system.”

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

Aspects of the present disclosure are described above with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, enable the implementation of the functions/acts specified in the flowchart and/or block diagram block or blocks. Such processors may be, without limitation, general purpose processors, special-purpose processors, application-specific processors, or field-programmable processors.

While the foregoing is directed to embodiments of the present disclosure, other and further embodiments of the disclosure may be devised without departing from the basic scope thereof, and the scope thereof is determined by the claims that follow.

1. A method for generating simulated engine sounds for simulated gear-shifting of a vehicle, the method comprising:
mapping a plurality of operating conditions of the vehicle to a plurality of respective simulated gears, wherein each of the operating conditions is associated with a throttle position and a vehicle speed;
configuring a plurality of simulated gear-shifting conditions based on threshold throttle positions and threshold vehicle speeds for simulated gear-shifting among respective simulated gears, wherein for each gear-shifting condition, at least some of the threshold vehicle speeds vary dependent of the throttle positions;
receiving a first operating condition of the vehicle, and selecting a first simulated gear from a plurality of respective simulated gears in response to the received first operating condition of the vehicle;
generating a first engine sound signal corresponding to the first simulated gear;
receiving a second operating condition of the vehicle;
determining a gear-shifting from the first simulated gear to a second simulated gear if the second operation condition reaches one of the plurality of simulated gear-shifting conditions; and
generating a second engine sound signal corresponding to the second simulated gear.

2. The method according to claim 1, further comprising:
classifying the simulated gear-shifting conditions into an upshifting condition set of simulated gear-shifting conditions and a downshifting condition set of simulated gear-shifting conditions;
determining whether a current throttle position is greater than a predetermined throttle threshold;
selecting the simulated gear-shifting conditions from the upshifting condition set of simulated gear-shifting conditions, if the current throttle position is greater than a predetermined throttle threshold; and
selecting the simulated gear-shifting conditions from the downshifting condition set of simulated gear-shifting conditions, if the current throttle position is less than or equal to the predetermined throttle threshold.

3. The method according to claim 1, wherein the configuring simulated gear-shifting conditions further comprising:
configuring gear-shifting lines based on threshold throttle positions and threshold vehicle speeds for simulated gear-shifting as the simulated gear-shifting conditions, wherein each of the gear-shifting lines represents a gear-shifting condition for a simulated gear-shifting among the plurality of respective simulated gears.

4. The method according to claim 3, wherein each of the gear-shifting lines is configured so that at least some of threshold vehicle speeds increases with the threshold throttle positions increase.

5. The method according to claim 3, wherein the gear-shifting lines are configured so that, for the same the threshold throttle position, the current gear is higher, the threshold vehicle speeds for gear-shifting is higher.

6. The method according to claim 1, wherein the method further comprising:
mapping the vehicle speed to an engine RPM for each gear of the gearbox.

7. The method according to claim 6, further comprising:
based on the first engine sound signal, driving at least one sound generation device of the vehicle to produce the first sound to simulate the operation in the first simulated gear; and
based on the second engine sound signal, driving at least one sound generation device of the vehicle to produce the second sound to simulate the operation in the second simulated gear.

8. The method according to claim 7,
wherein driving at least one sound generation device of the vehicle to produce the first sound to simulate the operation in the first simulated gear further comprising: generating varied sounds for the first gear as the engine RPM or the vehicle speed varies; and
wherein driving at least one sound generation device of the vehicle to produce the second sound to simulate the operation in the second simulated gear further comprising: generating varied sounds for the second gear as the engine RPM or the vehicle speed varies.

9. A system for generating simulated engine sounds for simulated gear-shifting of a vehicle comprising:
a storage device configured to:
store a mapping of a plurality of operating conditions of the vehicle to a plurality of respective simulated gears, wherein each of the operating conditions is associated with a throttle position and a vehicle speed; and
store a plurality of simulated gear-shifting conditions configured based on threshold throttle positions and threshold vehicle speeds for simulated gear-shifting among respective simulated gears, wherein for each gear-shifting condition, at least some of the threshold vehicle speeds vary dependent of the throttle positions; and
a processor configured to:
receive a first operating condition of the vehicle, and select a first simulated gear from a plurality of respective simulated gears in response to the received first operating condition of the vehicle;
generate a first engine sound signal corresponding to the first simulated gear;
receive a second operating condition of the vehicle;
determine a gear-shifting from the first simulated gear to a second simulated gear if the second operation condition reaches one of the plurality of simulated gear-shifting conditions; and
generate a second engine sound signal corresponding to the second simulated gear.

10. The system according to claim 9, wherein the simulated gear-shifting conditions are classified into an upshifting condition set of simulated gear-shifting conditions and a downshifting condition set of simulated gear-shifting conditions; and the processor is further configured to:
determine whether a current throttle position is greater than a predetermined throttle threshold;
select the simulated gear-shifting conditions from the upshifting condition set of simulated gear-shifting conditions, if the current throttle position is greater than a predetermined throttle threshold; and
select the simulated gear-shifting conditions from the downshifting condition set of simulated gear-shifting conditions, if the current throttle position is less than or equal to the predetermined throttle threshold.

11. The system according to claim 9, wherein the plurality of simulated gear-shifting conditions further comprising gear-shifting lines configured based on threshold throttle positions and threshold vehicle speeds for simulated gear-shifting as the simulated gear-shifting conditions, wherein each of the gear-shifting lines represents a gear-shifting condition for a simulated gear-shifting among the plurality of respective simulated gears.

12. The system according to claim 11, wherein each of the gear-shifting lines is configured so that at least some of threshold vehicle speeds increases with the threshold throttle positions increase.

13. The system according to claim 11, wherein the gear-shifting lines are configured so that, for the same the threshold throttle position, the current gear is higher, the threshold vehicle speeds for gear-shifting is higher.

14. The system according to claim 9, wherein the storage device is further configured to store the mapping of the vehicle speed to an engine RPM for each gear of the gearbox.

15. The system according to claim 9, wherein the processor is further configured to:
drive at least one sound generation device of the vehicle to produce the first sound to simulate the operation in the first simulated gear, based on the first engine sound signal; and
drive at least one sound generation device of the vehicle to produce the second sound to simulate the operation in the second simulated gear, based on the second engine sound signal.

16. The system according to claim 14, wherein the processor is further configured to:
drive at least one sound generation device of the vehicle to generate varied sounds for the first gear as the engine RPM or the vehicle speed varies; and
drive at least one sound generation device of the vehicle to generate varied sounds for the second gear as the engine RPM or the vehicle speed varies.
